(19) United States
(12) Patent Application Publication
(10) Pub. No.: US 2008/0048737 A1
(43) Pub. Date: Feb. 28, 2008

(54) Voltage Generating Circuit, Constant Current Circuit and Light Emitting Diode Driving Circuit

(76) Inventors: Tomoyuki Ito, Kyoto (JP); Isao Yamamoto, Kyoto (JP)

Correspondence Address: CANTOR COLBURN, LLP, 20 Church Street, 22nd Floor, Hartford, CT, 06103, US

(21) Appl. No.: 11/791,772

(22) PCT Filed: Oct. 26, 2005
(86) PCT No.: PCT/JP05/19673

§ 371 Date: May 25, 2007

(30) Foreign Application Priority Data
Nov. 30, 2004 (JP) 2004-345507

(51) Int. Cl. H02M 3/155; G05F 1/00; G05F 1/577; H03L 5/00; H03K 3/015; G06F 3/038

(52) U.S. Cl. 327/109; 327/332; 345/204

(57) ABSTRACT

A voltage generating circuit includes a voltage generating unit which generates plural constant voltages, plural switches, a control signal generating unit and a decoding circuit. The switches select any one of the plural constant voltages generated from the voltage generating unit and outputs it from a voltage output terminal. The control signal generating unit generates plural control signals which are switched between a high level and a low level through trimming on plural fuse resistors. The decoding circuit controls the state of connection of the switches-according to the control signals. The reference voltage Vx output from the voltage output terminal is applied to an electric-current generating resistor through an operational amplifier and a transistor to generate a constant electric current.

### BACKGROUND OF THE INVENTION

1. Field of the Invention

The present invention relates to a voltage generating circuit and a constant current circuit for generating a constant voltage and a constant electric current and, more particularly, relates to techniques for adjusting the constant voltage and the constant electric current.

2. Description of the Related Art

A plurality of voltage generating circuits and a plurality of constant current circuits for generating constant voltages and constant electric currents are used in various types of electronic circuits manufactured through semiconductor manufacturing processes, wherein such voltage generating circuits and constant current circuits are constituted by transistor devices and resistor devices. In cases of the occurrence of variabilities in the characteristics of such transistor devices and resistor devices during semiconductor manufacturing processes, it is impossible to generate a desired constant voltage and a desired constant electric current, thus inducing problems in circuits which require an accurate constant voltage or constant electric current.

An exemplary circuit which requires an accurate constant electric current is a circuit for driving a light emitting diode (hereinafter, abbreviated as an LED). Such an LED driving circuit controls a driving electric current flowing through an LED by connecting a constant current circuit to a cathode terminal of the LED. In this case, the driving electric current determines the brightness of light emitted from the LED and, therefore, variability in the electric current value of the driving electric current causes variability in the brightness of the emitted light. In order to overcome the problem, a repairing process is conducted in an inspection process for the LED driving circuit. In general, such a repairing process has been conducted using an adjustment circuit provided within the circuit, such that the driving electric current value approaches a desired electric current value.

A fuse resistor is provided in such an adjustment circuit, in some cases. The fuse resistor is a resistor which can be cut off by applying, thereto, laser irradiation or a voltage or an electric current greater than a threshold value (refer to Patent Literature 1).

[Patent Document 1] Japanese Patent Application Laid-open No. 2003-209175

An exemplary constant current circuit which adjusts an electric current through trimming on a fuse resistor is a circuit illustrated in FIG. 4. The constant current circuit of FIG. 4 includes an operational amplifier 10, a transistor 12, a constant current source 20, resistors R20 to R22, fuse resistors Rf21 and Rf22 and an electric-current generating resistor Ri1. An LED 310 is connected to an electric-current output terminal 202 in the constant current circuit 200′, so that the brightness of the emitted light is adjusted through a constant electric current Iled generated from the constant current circuit 200′.

In the constant current circuit 200′, the voltage applied to the electric-current generating resistor Ri1 is equal to the voltage Vx applied to the non-inverting input terminal of the operational amplifier 10. Accordingly, the electric current which flows through the constant current circuit 200′ and the LED 310 becomes Iled=Vx/Ri1. In cases of the occurrence of variabilities in the resistance values and the transistor characteristics during semiconductor manufacturing processes, it is impossible to generate a desired electric current value as the constant electric current Iled. Therefore, the fuse resistors Rf21 and Rf22 are provided in parallel with the resistors R21 and R22 so as to enable a method of adjusting the value of the constant electric current Iled generated by trimming.

However, the fuse resistors have resistance values of about several hundred ohms, which has made it difficult to provide an accuracy higher than the resistance values, with the constant current circuit 200′ in FIG. 4. For example, assuming that the resistor R20 is 1 kΩ and the resistors R21 and R22 are 50Ω, if the fuse resistors Rf21 and Rf22 have a resistance value of 200Ω, the resistance value of the fuse resistors determines the accuracy of the voltage adjustment. If an attempt is made to provide an accuracy of about several percent with this circuit structure, there is a need for significantly increasing the resistance value of the resistor R20, which means increasing the chip size of the LED driving circuit.

### SUMMARY OF THE INVENTION

The present invention was made in view of the aforementioned problem and general purpose of the invention is to provide a voltage generating circuit capable of adjusting a voltage value with higher accuracy, and a constant current circuit and a light emitting diode driving circuit which employ the same.

In order to overcome the aforementioned problem, a voltage generating circuit according to an embodiment of the present invention includes a voltage generating unit which generates plural constant voltages; switches for selecting a predetermined constant voltage, out of the plural constant voltages generated by the voltage generating unit; a control signal generating unit which generates plural control signals which are switched in signal level by arbitrarily cutting off plural fuse devices; and a decoding circuit which controls the state of connection of the switches according to the combination of the signal levels of the plural control signals generated by the control signal generating unit, and output a single constant voltage selected through the switches.

According to this embodiment, even in cases of the occurrence of variabilities in the characteristics of transistors and resistors due to variabilities in semiconductor manufacturing processes, it is possible to select and output a voltage closest to a desired voltage, out of the plural constant voltages generated from the voltage generating unit by performing trimming on the fuse resistors.

The voltage generating unit may include a group of resistors which is constituted by plural resistors connected in series to one another, and a constant voltage source which applies a voltage between the opposite ends of the group of resistors, and may output respective voltages which appear at the connection points among the plural resistors as the plural constant voltages.

By appropriately selecting the resistance values of the plural resistors, it is possible to adjust the potential differences across the plural constant voltages generated from the voltage generating unit.

The voltage generating unit may include a group of resistors which is constituted by plural resistors connected in series to one another, and a constant current source which flows a constant electric current through the group of resistors, and may output respective voltages which appear at the connection points among the plural resistors as the plural constant voltages.

The group of the plural resistors may include a base resistor which determines a minimum voltage value, and plural adjustment resistors which are determined according to the potential differences across the plural constant voltages.

According to another embodiment of the present invention, there is provided a constant current circuit which draws a constant electric current through an electric-current output terminal. The constant current circuit includes: a transistor and a resistor provided in series between the electric-current output terminal and a ground potential; an operational amplifier, the connection point between the transistor and the resistor being connected to its inverting input terminal, and a control terminal of the transistor being connected to its output terminal; and the aforementioned voltage generating circuit which applies a constant voltage to the non-inverting input terminal of the operational amplifier.

According to this embodiment, it is possible to adjust the voltage applied to the non-inverting input terminal of the operational amplifier, by performing trimming on the fuse resistors in the voltage generating circuit. This enables adjusting the voltage applied to the resistor provided in series to the transistor. As a result, it is possible to adjust the electric current which flows through the resistor, thereby controlling the electric current which flows through the electric-current output terminal to a desired electric current value.

According to further a different embodiment of the present invention, there is provided a light emitting diode driving circuit. This light emitting diode driving circuit includes the aforementioned constant current circuit which is connected to a cathode terminal of a light emitting diode to be driven; and a voltage source which supplies a driving voltage to an anode terminal of the light emitting diode.

According to this embodiment, it is possible to adjust the electric current which flows into the light emitting diode via the electric-current output terminal to a desired electric current value, with the constant current circuit, thereby adjusting the brightness of the light emitting diode.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram illustrating the structure of an electronic device which preferably employs a voltage generating circuit and a constant-current source according to an embodiment.

FIG. 2 is a circuit diagram illustrating the structure of the constant current circuit according to the embodiment.

FIG. 3 is a view illustrating an exemplary combination of control signals and switch control signals.

FIG. 4 is a circuit diagram illustrating an exemplary conventional constant current circuit which adjusts an electric current through trimming on fuse resistors.

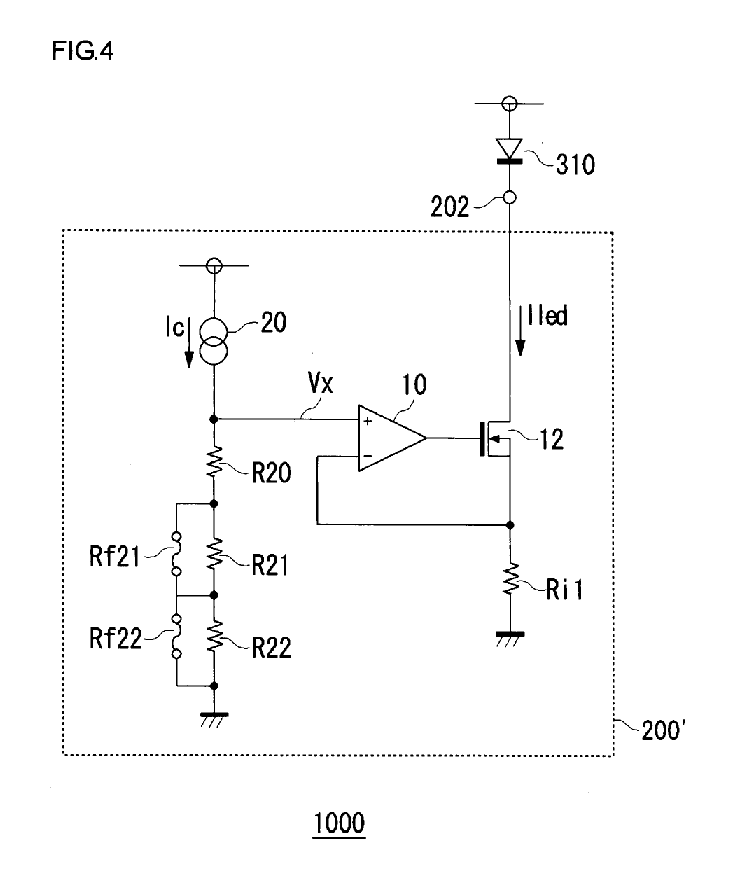

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

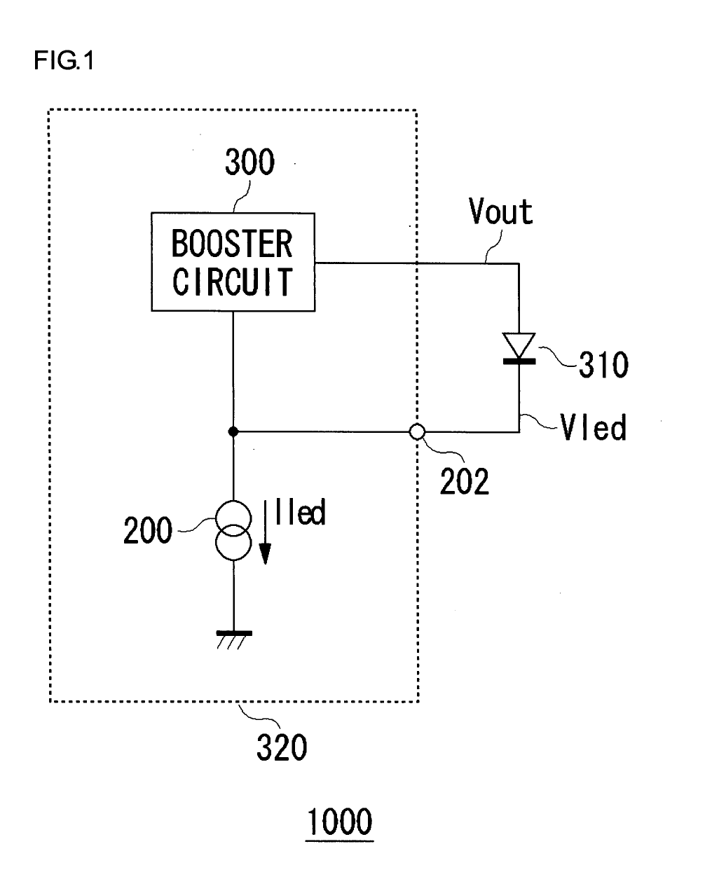

FIG. 1 is a circuit diagram illustrating the structure of an electronic device 1000 which preferably employs a voltage generating circuit and a constant-current source according to the present embodiment. This electronic device 1000 includes an LED 310 and an LED driving circuit 320. The electronic device 1000 is a mobile phone terminal, a PDA, a portable CD player or a notebook personal computer, and the LED 310 is provided as a back light of a liquid crystal display panel or a light emitting device for notifying a user of arrival of an incoming call. The LED driving circuit 320 includes a booster circuit 300 which supplies a driving voltage to the LED 310 to be driven, and a constant current circuit 200 which stabilizes the current flowing through the LED 310. The booster circuit 300 is constituted by a common switching regulator or charge pump circuit and generates a voltage required for stepping up a battery voltage and the like for driving the LED 310. The output voltage Vout output from the booster circuit 300 is applied to an anode terminal of the LED 310.

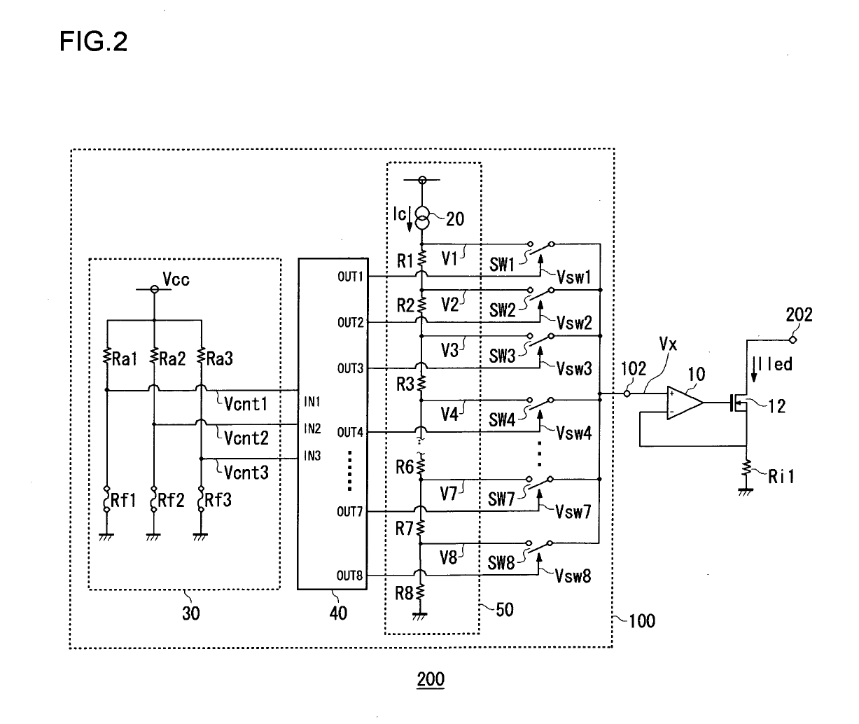

The constant current circuit 200 in the LED driving circuit 320 is connected to a cathode terminal of the LED 310. The constant current circuit 200 controls the electric current flowing through the LED 310 to a constant electric current Iled. The voltage at the cathode terminal of the LED 310 is fed back to the booster circuit 300. The booster circuit 300 controls the output voltage Vout such that the voltage Vled at the cathode terminal of the LED 310 becomes a predetermined voltage. In general, the target value of the voltage Vled at the cathode terminal of the LED 310 is set such that a transistor 12, which is a constituent of the constant current circuit 200 in FIG. 2 which will be described later, is not saturated.

In cases of forming the LED driving circuit 320 having the aforementioned structure integrally on a semiconductor substrate made of silicon or the like, the value of the constant electric current Iled becomes different from a desired value, due to the variabilities in the characteristics of the resistors and the transistors constituting the constant current circuit 200 which are induced during manufacturing processes. Accordingly, the constant current circuit 200 according to the present embodiment is structured to include fuse resistors, which enables adjusting finely the value of the constant electric current Iled to a desired value Iref through trimming of the fuse resistors.

FIG. 2 is a circuit diagram illustrating the structure of the constant current circuit 200 according to the present embodiment. The constant current circuit 200 includes a voltage generating circuit 100, an operational amplifier 10, a transistor 12 and an electric-current generating resistor Ri1 and induces a constant electric current Iled flowing through the circuit connected to an electric-current output terminal 202.

The voltage generating circuit 100 generates a reference voltage Vx and outputs it from a voltage output terminal 102. The voltage output terminal 102 of the voltage generating circuit 100 is connected to the non-inverting input terminal of the operational amplifier 10, so that the reference voltage Vx is applied to the non-inverting input terminal of the operational amplifier 10.

The transistor 12 is an N-channel MOS transistor and is connected at its gate terminal to the output terminal of the operational amplifier 10, connected at its source terminal to the inverting input terminal of the operational amplifier 10 and connected at its drain terminal to the electric-current output terminal 202.

The electric-current generating resistor Ri1 is provided between the source terminal of the transistor 12 and the ground.

The operational amplifier 10 performs feedback control on the gate voltage of the transistor 12 which is output from the operational amplifier 10, such that the voltage at the non-inverting input terminal equals to the voltage at the inverting input terminal. Since the voltage Vx generated from the voltage generating circuit 100 is applied to the non-inverting input terminal of the operational amplifier 10, the drain voltage of the transistor 12 becomes equal to the reference voltage Vx. Since the electric-current generating resistor Ri1 is connected to the drain terminal of the transistor 12, the reference voltage Vx is applied to the electric-current generating resistor Ri1.

This results in an electric current represented by Vx/Ri1 flowing through the electric-current generating resistor Ri1. This electric current becomes the constant electric current Iled flowing through the LED 310 connected to the electric-current output terminal 202.

Next, there will be described the structure of the voltage generating circuit 100 which creates the reference voltage Vx and outputs it to the non-inverting input terminal of the operational amplifier 10. This voltage generating circuit 100 includes a control signal generating unit 30, a decoding circuit 40, a voltage generating unit 50, and first to eighth switches SW1 to SW8.

The voltage generating unit 50 includes a constant current source 20 and a group of resistors which is constituted by first to eighth adjustment resistors R1 to R8. The group of resistors, which is constituted by the first to eighth adjustment resistors R1 to R8 connected in series to one another, is connected at its one end to the ground and also is connected at its other end to the constant current source 20. The constant current source 20 supplies a constant electric current Ic to the group of resistors. The voltage generating unit 50 outputs voltages which appear at the connection points among respective adjacent adjustment resistors R1 to R8, as plural constant voltages V1 to V8.

For example, assuming that the constant electric current Ic supplied from the constant current source 20 is set to 100 μA, the eighth adjustment resistor R8 is set to 900Ω, and the values of the first to seventh adjustment resistors R1 to R7 are set to 50Ω, it is possible to create constant voltages in the range of 80 mV to 115 mV in 5-mV steps, as the respective constant voltages V1 to V8, which enables adjusting the constant voltages V1 to V8 around a center value of 100 mV at a constant voltage V4, in the range of from 100 mV −20 mV to 100 mV +20 mV, with an accuracy of about 5%.

Among the constant voltages V1 to V8 generated from the voltage generating unit 50, a single voltage is selected through the first to eighth switches SW1 to SW8 and then is output from the voltage output terminal 102 of the voltage generating circuit 100. The control signal generating unit 30 and the decoding circuit 40 control the state of the connection of the first to the eighth switches SW1 to SW8. Also, as an alternative example, plural switches can be turned on at the same time to output an intermediate voltage among the constant voltages V1 to V8. For example, when the second switch SW2 and the third switch SW3 are turned on at the same time, it is possible to output a voltage intermediate between the constant voltages V2 and V3.

The control signal generating unit 30 includes first to third resistors Ra1 to Ra3 and first fuse resistors Rf1 to Rf3 and outputs three control signals Vcnt1 to Vcnt3 which can be switched between a high level and a low level through trimming of the fuse resistors Rf1 to Rf3.

The first resistor Ra1 and the first fuse resistor Rf1 are connected in series to each other, and one end thereof is connected to the ground, while a voltage Vcc is applied to the other end thereof. The voltage at the connection point between the first resistor Ra1 and the first fuse resistor Rf1 is output as a first control signal Vcnt1. A second control signal Vcnt2 and a third control signal Vcnt3 are generated in the same way.

The fuse resistors can be molten to be cut off by applying laser irradiation thereto or by applying, thereto, a voltage or an electric current greater than a predetermined threshold value. The resistance values of the first to third resistors Ra1 to Ra3 are set to be sufficiently higher than the resistance values of the fuse resistors Rf1 to Rf3. Since the fuse resistors Rf1 to Rf3 have sufficiently lower resistance values, in cases where the first fuse resistor Rf1 in the control signal generating unit 30 is not cut off, an electric current flows through the first resistor Ra1 and the first fuse resistor Rf1, which causes a first control signal Vcnt1 at a low level, due to the voltage drop across the first resistor Ra1.

On the contrary, when the first fuse resistor Rf1 is cut off, no electric current flows through the first resistor Ra1, which causes no voltage drop there across, thereby causing a first control signal Vcnt1 at a high level to be output.

As described above, the control signal generating unit 30 is capable of switching the first to third control signals Vcnt1 to Vcnt3 between a high level and a low level, though the combination of trimmings of the three fuse resistors Rf1 to Rf3.

The decoding circuit 40 includes three digital input terminals IN1 to IN3 and eight digital output terminals OUT 1 to OUT8. The control signals Vcnt1 to Vcnt3 output from the control signal generating unit 3 are input to the digital input terminals IN1 to IN3. The decoding circuit 40 analyzes the three bits of the three control signals Vcnt1 to Vcnt3, namely 8 types of combinations of high and low, and controls switch control signals Vsw1 to Vsw8 output from the eight digital output terminals OUT1 to OUT8.

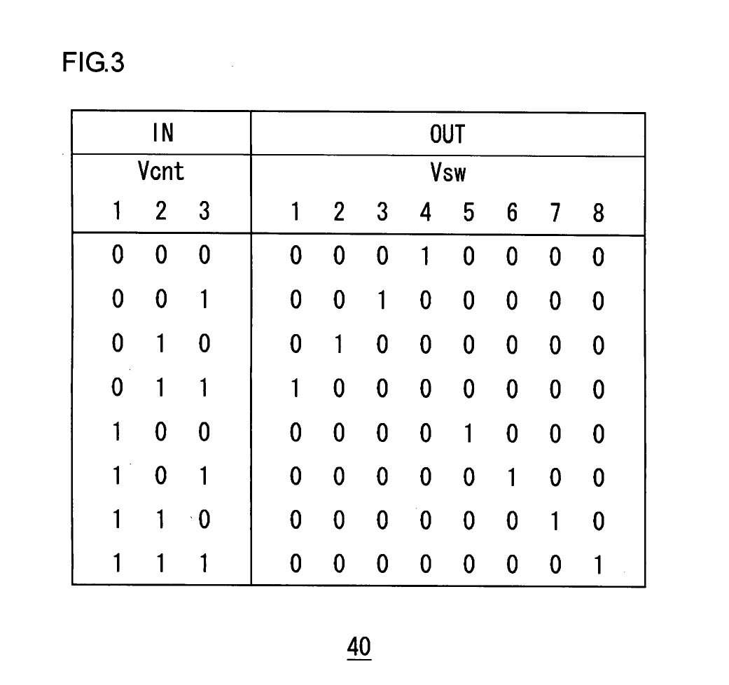

FIG. 3 illustrates an exemplary combination of control signals Vcnt1 to Vcnt3 input to the digital input terminals IN1 to IN3 and switch control signals Vsw1 to Vsw8 output from the digital output terminals OUT1 to OUT8. The first to eighth switches SW1 to SW8 are switched between ON and OFF, through the eight switch control signals Vsw1 to Vsw8 output from the decoding circuit 40.

In FIG. 3, “1” corresponds to the high level of the control signals Vcnt1 to Vcnt3 input to the digital input terminals IN1 to IN3, while “0” corresponds to the low level thereof. Thus, 8 states can be controlled through the combination of the states of trimming of the first to third fuse resistors Rf1 to Rf3. When the i-th switch control signal Vswi, out of the switch control signals Vsw1 to Vsw8 output from the digital output terminals OUT1 to OUT8, is set to 1, the i-th switch SW1 is caused to be at an ON state. When the switch control signal Vswi is set to 0, the i-th switch SW1 is caused to be at an OFF state.

Namely, as illustrated in FIG. 3, the voltage generating circuit 100 is capable of turning on any one of the first to eighth switches SW1 to SW8 while turning off the other switches, according to the combination of the control signals Vcnt1 to Vcnt3, thus outputting an optimum voltage out of the constant voltages V1 to V8 from the voltage output terminal 102.

At an initial state where no trimming has been performed on any of the fuse resistors Rf1 to Rf3, all the control signals Vcnt1 to Vcnt3 are set to 0, and only the switch control signal Vsw4 is set to 1. As a result, only the fourth switch SW4 is turned on, while the other switches are set to be off, which causes the connection point between the third adjustment resistor R3 and the fourth adjustment resistor R4 to be connected to the voltage output terminal 102, thereby resulting in outputting a constant voltage V4 as a center value, out of the plural constant voltages V1 to V8.

Hereinafter, there will be described a method for adjusting the constant electric current Iled flowing through the LED 310, in the LED driving circuit 320 having the aforementioned structure.

The characteristics of resistors and transistor devices formed in semiconductor integrated circuits are varied on a lot-by-lot basis during semiconductor manufacturing or a wafer-by-wafer basis or depending on the chip position within a single wafer. This results in variabilities in the resistance values of the adjustment resistors R1 to R8 and the value of the constant electric current Ic generated from the constant current source 20 in the voltage generating unit 50, thereby resulting in variabilities in the electric potentials at the connection points between respective adjacent resistors R1 to R8.

Furthermore, this results in variability in the electric-current generating resistor Ri1 in the constant current circuit 200, thereby causing variability in the value of the constant electric current Iled=Vx/Ri1 which flows through the LED 310.

In order to address this, at first, the value of the constant electric current Iled is determined at an initial state where no trimming has been performed on the fuse resistors Rf1 to Rf3, in an inspection process for the LED driving circuit 320.

As described above, the voltage generating circuit 100 outputs a constant voltage V4 which is to be a center value, out of the plural constant voltages V1 to V8, at an initial state where no trimming has been performed on the fuse resistors Rf1 to Rf3. At the state where the constant voltage V4 is output from the voltage output terminal 102, the constant electric current flowing through the LED 310 is expressed as Iled=V4/Ri1.

In this case, the adjustment resistors R1 to R8 are all provided within a single chip such that they are close to one another and, therefore, it can be considered that they have substantially the same variabilities in width, length and thickness. In this case, the resistance values of the adjustment resistors R1 to R8 are varied uniformly with substantially the same rate. As a result, even in cases of the occurrence of variabilities in the resistance values and the constant electric current Ic, the relative ratio among the respective constant voltages V1 to V8 is not changed. Namely, the constant voltages V1 to V8 generated by the voltage generating unit 50 are varied as follows. If the constant value V4 as the center value is varied by 10%, the other constant voltages V1 to V3 and V5 to V8 are also varied by 10% along therewith.

If the constant electric current Iled determined at an initial state is greater by 10% than a target value Iref, it can be considered that the voltage generated from the voltage generating circuit 100 is set to be lower by about 10%. Since the constant voltage V4 is output at the initial state, a constant voltage V6 which is lower by 10% than the constant voltage V4 can be output for making the value of the constant electric current Iled closer to the target value, by switching the switches SW.

In order to output the constant voltage V6, the sixth switch SW6 can be turned on and, therefore, trimming can be performed on the first fuse resistor Rf1 and the third fuse resistors Rf3, as can be seen from FIG. 3.

On the contrary, if the constant electric current Iled determined at an initial state is smaller by 15% than a target value Iref, the voltage generated from the voltage generating circuit 100 can be set to be higher by about 15% and, therefore, the first switch SW1 can be turned on to output a constant voltage V1 for making the value of the constant electric current Iled closer to the target value.

As described above, with the LED driving circuit 320 according to the present embodiment, it is possible to adjust the value of the constant electric current Iled through trimming on the fuse resistors Rf in the voltage generating circuit 100, in an inspection process. As a result, even in the case of the occurrence of variabilities in resistors and transistor characteristics during the semiconductor manufacturing processes, it is possible to cause the LED 310 to emit light with a desired brightness.

The voltage generating circuit 100 according to the present embodiment employs the fuse resistors which are to be subjected to trimming, in order to create control signals having binary values at high and low levels, not using them as resistors at portions at which voltages or electric currents should be generated. As a result, it is possible to set the accuracy of the constant voltages generated from the voltage generating circuit 100, with the adjustment resistors connected in series to one another, regardless of the resistance values of the fuse resistors.

It will be appreciated by those skilled in the art that the aforementioned embodiment is merely illustrative, various changes could be made to the combination of respective components and respective processing processes and also such changes fall within the scope of the invention.

For example, a constant voltage source can be substituted for the constant current source 20 in the voltage generating unit 50 in FIG. 2. In this case, similarly, it is possible to divide a constant voltage supplied from the constant voltage source through resistors and to output the resultant plural constant voltages from the connection points between the respective adjacent adjustment resistors R1 to R8, thereby offering the same effects as those of the embodiment.

Further, while there has been described a case where eight resistors as adjustment resistors are connected in series to one another in the voltage generating unit 50 in the voltage generating circuit 100 according to the embodiment, the adjustment resistors are not limited thereto, and the resistance values of adjustment resistors and the number of resistors can be determined depending on the range and the accuracy of adjustment of the reference voltage Vx to be output from the voltage output terminal 102. When 16 adjustment resistors are connected in series to one another, a 4-bit decoding circuit 40 can be employed and, also, the control signal generating unit 30 can be adapted to generate four control signals.

In the embodiment, the components which constitute the voltage generating circuit 100, the constant current circuit 200 and the LED driving circuit 320 can be all integrated with one another or some of them can be formed from discrete components. The portions to be integrated with one another, can be determined depending on the cost and the occupied area.

While the preferred embodiments of the present invention have been described using specific terms, such description is for illustrative purposes only, and it is to be understood that changes and variations may be made without departing from the spirit or scope of the appended claims.

1. A voltage generating circuit comprising:
a voltage generating unit which generates plural constant voltages;
switches for selecting a predetermined constant voltage, out of the plural constant voltages generated by the voltage generating unit;
a control signal generating unit which generates plural control signals which are switched in signal level by arbitrarily cutting off plural fuse devices; and
a decoding circuit which controls the state of connection of the switches according to the combination of the signal levels of the plural control signals generated by the control signal generating unit,
wherein a single constant voltage selected through the switches is output.

2. The voltage generating circuit according to claim 1, wherein
the voltage generating unit comprises a group of resistors which is constituted by plural resistors connected in series to one another, and a constant voltage source which applies a voltage between the opposite ends of the group of resistors, and outputs respective voltages which appear at the connection points among the plural resistors as the plural constant voltages.

3. The voltage generating circuit according to claim 1, wherein
the voltage generating unit comprises a group of resistors which is constituted by plural resistors connected in series to one another, and a constant current source which flows a constant electric current through the group of resistors, and outputs respective voltages which appear at the connection points among the plural resistors as the plural constant voltages.

4. A constant current circuit which draws a constant electric current through an electric-current output terminal, comprising:
a transistor and a resistor provided in series between the electric-current output terminal and a ground potential;
an operational amplifier, the connection point between the transistor and the resistor being connected to its inverting input terminal, and a control terminal of the transistor being connected to its output terminal; and
the voltage generating circuit according claim 1 which applies a constant voltage to the non-inverting input terminal of the operational amplifier.

5. A light emitting diode driving circuit comprising:
the constant current circuit according to claim 4 which is connected to a cathode terminal of a light emitting diode to be driven; and
a voltage source which supplies a driving voltage to an anode terminal of the light emitting diode.

6. An electronic device comprising:
a light emitting diode; and
the light emitting diode driving circuit according to claim 5 which drives the light emitting diode.
